(19) United States
(12) Patent Application Publication
(10) Pub. No.: US 2025/0384196 A1
(43) Pub. Date: Dec. 18, 2025

(54) SYSTEMS AND METHODS FOR SCALABLE CHIP-LEVEL PERSONALIZATION

(71) Applicant: Keyfactor, Inc., Independence, OH (US)

(72) Inventors: Guillaume CRINON, Douvres-la-Delivrande (FR); Tomas GUSTAVSSON, Stockholm (SE)

(21) Appl. No.: 18/933,086

(22) Filed: Oct. 31, 2024

(30) Foreign Application Priority Data
Jun. 18, 2024 (FR) 2406518
Aug. 8, 2024 (FR) 2408777

(51) Int. Cl. G06F 30/343

(52) U.S. Cl. CPC G06F 30/343

(57) ABSTRACT

Methods, systems, and computer program products for implementing a scalable chip-level personalization process. A request for a batch of programmable integrated circuits (ICs) is received. The request includes a set of configuration elements to be implemented for each programmable IC. A unique configuration key pair corresponding to the batch of programmable ICs based on the set of configuration elements is determined. A corresponding configuration certificate is obtained in response to submitting the unique configuration key pair to a Certificate Authority for signature. A configuration file is obtained and updated by encrypting and signing the configuration file based on the unique configuration key pair. The batch of programmable ICs are generated. The configuration certificate for each programmable IC is encrypted. The batch of the programmable ICs, the updated configuration file, and the corresponding batch of encrypted configuration certificates is provided to a client device.

### CROSS-REFERENCE TO RELATED APPLICATIONS

This application claims priority to French Provisional Application No. 2406518, filed Jun. 18, 2024, and French Provisional Application No. 2408777, filed Aug. 8, 2024, which are hereby incorporated by reference herein in their entirety.

### TECHNICAL FIELD

The present disclosure generally relates to computers and computer software, and more specifically, to methods, systems, and computer program products for implementing a scalable chip-level personalization process.

### BACKGROUND

Microcontrollers (MCU) and microprocessors (MPU) represent a large global market. With a permanent objective to reduce costs, these two families of products are driving Moore's law and the race to finer lithography and fundamental transistor size. But the advantage of smaller dies per silicon wafer is partly offset by the increasing cost of the set of masks used in the many photolithography steps. Furthermore, each MCU or MPU is declined into a n×m×p matrix of products which are marketed at different costs for different usage. Behind each MCU or MPU, there is a specific product reference which ties back to a specific silicon die. As a consequence, each MCU or MPU family requires an investment in a large number of sets of photolithography masks, and as many wafer and product SKUs down to the sales and distribution chain. All of the above may negatively impact profitability and market prices.

In addition to this, Original Equipment Manufacturers (OEMs) assembling machines and appliances from these MCUs/MPUs may be interested in the possibility to mutualize their own hardware design or upgrade their products in time without touching the hardware design to add more memory, unlock some crypto accelerators, and/or boost the performance of some peripherals like an Analog-to-Digital Converter (ADC). Thus, the multiple different product references with different variations provide a unique and expensive challenge for manufacturers to try and reduce costs.

Some of the prior techniques describe systems for distributing a configuration file (e.g., a design package) into a field programmable gate array (FPGA) with a configuration file protected by a specific key so that only allowed users/workloads can unlock the package. These prior techniques allow hyperscalers to sell FPGA-accelerated functionalities to their customers that share a common hardware platform, that provide software packages that are signed and protected, and that only permit paying customers can use them. However, these techniques only apply to FPGAs, are not designed to help the silicon vendor reduce costs, do not bear the notion of product batches, and articulates around a “management payload” that needs to be loaded on the FPGA to constantly monitor usage and trigger billing, and because the hardware server and the software package are developed and managed by the same entity (e.g., a hyperscaler), there's no need for project/customer-specific key. Therefore, improved solutions for implementing a scalable chip-level personalization processes for the MCU/MPU industry are needed.

### SUMMARY

In embodiments of the invention, a method for implementing a scalable chip-level personalization process is provided. The method, at an electronic device having a processor, includes the actions of receiving, at a server, a request for a batch of programmable integrated circuits (ICs) from a client device, wherein the request includes a set of configuration elements to be implemented for each programmable IC of the batch of programmable ICs. The method further includes the actions of determining a unique configuration key pair corresponding to the batch of programmable ICs based on the set of configuration elements. The method further includes the actions of, in response to submitting the unique configuration key pair to a Certificate Authority for signature, obtaining a corresponding configuration certificate. The method further includes the actions of obtaining a configuration file from a configuration database based on the set of configuration elements, updating the configuration file by encrypting and signing the configuration file based on the unique configuration key pair. The method further includes the actions of generating the batch of programmable ICs based on the updated configuration file. The method further includes the actions of encrypting the configuration certificate for each programmable IC of the batch of programmable ICs. The method further includes the actions of providing the batch of the programmable ICs, the updated configuration file, and the corresponding batch of encrypted configuration certificates to the client device.

These and other embodiments can each optionally include one or more of the following features.

In some embodiments of the invention, each programmable IC of the batch of the programmable ICs is configured to decrypt and validate the configuration certificate and validate and decode the configuration file. In some embodiments of the invention, decoding of the configuration file by a programmable IC implements a configuration that is based on the set of configuration elements associated with configuration file.

In some embodiments of the invention, the unique configuration key pair and certificate corresponding to the batch of programmable ICs are based on: i) a public-key infrastructure, ii) an elliptic curve cryptography (ECC) cryptosystem, or a combination thereof.

In some embodiments of the invention, the unique configuration key pair and certificate corresponding to the batch of programmable ICs is based on: i) an Advanced Encryption Standard (AES) algorithm that uses that uses a 256-bit key, ii) a keyed-hashing for message authentication algorithm, or a combination thereof.

In some embodiments of the invention, the unique configuration key pair and certificate corresponding to the batch of programmable ICs are based on a quantum-resistant algorithm.

In some embodiments of the invention, the unique configuration key pair and certificate includes project-specific and client-specific configuration keys and certificates associated with a client corresponding to the client device.

In some embodiments of the invention, updating the configuration file by encrypting and signing the configuration file based on the unique configuration key pair includes obtaining the configuration file from a configuration database.

In some embodiments of the invention, generating the batch of programmable ICs based on the updated configuration file includes generating a unique serial number for each programmable IC of the batch of programmable ICs, generating and programming one or more unique private and public key pairs each programmable IC of the batch of programmable ICs, and programming each programmable IC of the batch of programmable ICs with a corresponding certificate.

This summary is provided to introduce a selection of concepts in a simplified form that are further described below in the detailed description. This summary is not intended to identify key features or essential features of the claimed subject matter, nor is it intended to be used in isolation as an aid in determining the scope of the claimed subject matter.

### BRIEF DESCRIPTION OF DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 illustrates an example operating environment for implementing a scalable chip-level personalization process, according to embodiments of the invention.

FIG. 2 illustrates an example chart for different product configurations of a manufacturer, according to embodiments of the invention.

FIG. 3 illustrates an example process of generating a configuration file associated with a selected configuration based on a set of configuration elements, according to embodiments of the invention.

FIG. 4 illustrates an example of generating two different chip-level configurations, according to embodiments of the invention.

FIG. 5 is a flowchart of an example scalable chip-level personalization process, according to embodiments of the invention.

FIG. 6 is a block diagram showing an example computer architecture for a computer capable of executing the software components described herein, according to embodiments described herein.

### DETAILED DESCRIPTION

Generally, systems, methods, devices, and techniques are provided for implementing a scalable chip-level personalization process. This invention describes a system architecture allowing a silicon vendor to manufacture generic microcontrollers/microprocessors hardware and create a constellation of products with different features which can be unlocked with non-tamperable customer project-dedicated configuration files during manufacturing or by an over-the-air field firmware upgrade. Some implementations of the invention use mutualizing of a common hardware die for a family of products and allow configuration of the hardware on a per customer per project basis with a firmware configuration file with cryptographic properties such that a given configuration for a given customer project and a given batch of microchips cannot be fraudulently reused and applied to another batch of microchips for the same or another project or customer.

Some prior techniques validate a license attached to a silicon design. Such an engine may be used to validate, decrypt, and apply a given configuration package on an MCU or MPU (hereinafter referred to as “MCU”) to allow unlocking some silicon functionalities on a chip. However, these techniques may only focus on licenses which expire and how they can be renewed, may be limited in scope to the validation engine sitting on the MCU and the license server, may require the OEM to use the chip to build a specific license service on the board itself, may not describe how configurations are built, protected, and licenses used, and may not bear the notion of product batches. Therefore, improved solutions for implementing a scalable chip-level personalization processes for the MCU industry are needed.

The embodiments of the invention aim to improve upon prior techniques by mutualizing a common hardware die for a family of products and to allow configuration of the hardware on a per customer per project basis with a firmware configuration file with cryptographic properties such that a given configuration for a given customer project and a given batch of microchips cannot be fraudulently reused and applied to another batch of microchips for the same or another project or customer. In other words, the embodiments of the invention may provide different combinations that a client may order for a batch of programmable integrated circuits (ICs) (e.g., receiving an order at a silicon provider server for a given product by a customer for a given customer project).

In an exemplary implementation, generic MCU hardware may contain an engine which can validate and decode a configuration file during secure boot and apply such configuration. The silicon vendor establishes Config_CA, an Issuing CA within his Public Key Infrastructure This implementation relies on the fact that each MCU comes with a unique serial number and at least one unique Private (MCU_Pr) and Public (MCU_Pu) key pair bound by an asymmetric cryptography algorithm, such as and not limited to RSA or ECC and the Config_CA certificate adequately stored in a secure enclave or memory where it cannot be overridden. Upon manufacturing MCUs/MPUs, the silicon vendor maintains a database MCU_DB of serial numbers and MCU_Pu which can be accessed later on. The MCU vendor defines the family of products with a multi-dimensional matrix of features. For each specific product within the family, a unique configuration file is created and stored in the database of configurations (Config_DB). The family of products is advertised and marketed as usual.

In some implementations, upon receiving an order for a given product by a customer for a given customer project, the silicon vendor creates in his system a new key pair (Config_Pr and Config_Pu) bound by an asymmetric cryptography algorithm, such as and not limited to RSA or ECC. The silicon vendor then signs Config_Pu into Config_cert, an x.509 certificate issued by Config_CA The silicon vendor may retrieve from Config_DB the configuration file corresponding to the product requested by the customer and use Config_Pr to encrypt and sign the configuration file. The silicon vendor may prepare the batch of MCUs/MPUs to be sent to the customer. Each chip may be identified by a respective serial number. The silicon vendor may then retrieve for each chip the corresponding MCU_Pu from MCU_DB. For each chip, the silicon vendor will encrypt Config_cert, the certificate used to verify the signature and decrypt a given configuration, with MCU_Pu.

In some implementations of the invention, the silicon vendor may deliver an order to the customer for N #MCU/MPU chips, an encrypted and signed configuration file, and an N #MCU_Pu-encrypted Config_cert certificates: MCU_Config_cert. In some implementations of the invention, upon manufacturing, an OEM receiving the order may inject into each MCU/MPU the shared encrypted and signed configuration file and the MCU/MPU-specific MCU_Config_cert certificate. In some implementations of the invention, with an adequate engine, at secure boot, the MCU code may decrypt MCU_Config_cert using its unique MCU_Pr, verify the validity of Config_cert using the Config_CA certificate and extract Config_Pu, use Config_Pu to validate the signature and decrypt the configuration file, and apply the configuration file and unlock the requested features corresponding to the product ordered.

The technology in this disclosure is related to systems and methods for implementing a scalable chip-level personalization process. Several advantages may be obtained using these processes. For example, the configuration files cannot be hacked and stolen because Config_Pu keys remain secret and only shared encrypted for each MCU (e.g., configuration files cannot be consumed for extra production by customer or gray market). In the event a configuration file should leak in clear text from the silicon vendor system and a rogue actor encrypts this configuration file with his own rogue configuration private key, the corresponding public key would need to be passed to the MCU in the form of an x.509 certificate signed by the silicon vendor, making the hack much more difficult to succeed. Additionally, one configuration key applies to a batch of products, allowing to share the same encrypted configuration file for the same family of OEM products, therefore simplifying initial firmware programing and subsequent over-the-air updates which can be broadcast and do not have to be MCU-specific. Moreover, an OEM can buy from the silicon vendor a configuration upgrade at any time after deploying a family of products (e.g., a broadcast firmware update can carry the new configuration for a fleet of identical products). Furthermore, regarding sales, marketing, and manufacturing, these business processes may not be disrupted, as customers may pay for what they use, silicon vendors may mutualize the costs of silicon manufacturing among a family of products, and silicon vendors may monetize MCU features as an after-market sale.

More specifically, this technology includes a method that includes at an electronic device having a processor, receiving, at a server, a request for a batch of programmable integrated circuits (ICs) from a client device, wherein the request includes a set of configuration elements to be implemented into each programmable IC of the batch of programmable ICs (e.g., receiving an order at a silicon provider server for a given product by a customer for a given customer project). The method may further include setting-up a specific Public Key Infrastructure (PKI) where Config_CA an issuing CA can sign Config public keys and manufacturing each MCU with the Config_CA certificate in a memory protected from overwriting. The method may further include determining a unique configuration key pair (project/customer-specific keys) corresponding to the batch of programmable ICs based on the set of configuration elements (e.g., upon receiving an order for a given product by a customer for a given customer project, the silicon vendor creates in his system a new key pair (Config_Pr and Config_Pu) bound by an asymmetric cryptography algorithm, such as and not limited to RSA or ECC). The method may further include signing Config_Pu into Config_cert with Config_CA. The method may further include obtaining a configuration file from a configuration database based on the set of configuration elements. The method may further include updating the configuration file by encrypting the configuration file based on the unique configuration key pair (e.g., a silicon vendor may retrieve from the Config_DB the configuration file corresponding to the product requested by the customer and uses Config_Pr to encrypt and sign the configuration file). The method may further include generating the batch of programmable ICs based on the updated configuration file (e.g., a silicon vendor prepares the batch of MCUs/MPUs to be sent to the customer, each chip is identified by its serial number, and the silicon vendor can then retrieve for each chip the corresponding MCU_Pu from MCU_DB). The method may further include encrypting the configuration certificate Config_cert with each MCU_Pu determining a batch of MCU-specific decryption certificates associated with the encrypted configuration file. The method may further include providing the batch of programmable ICs, the updated configuration file, and the corresponding batch of decryption certificates to a client associated with the client device.

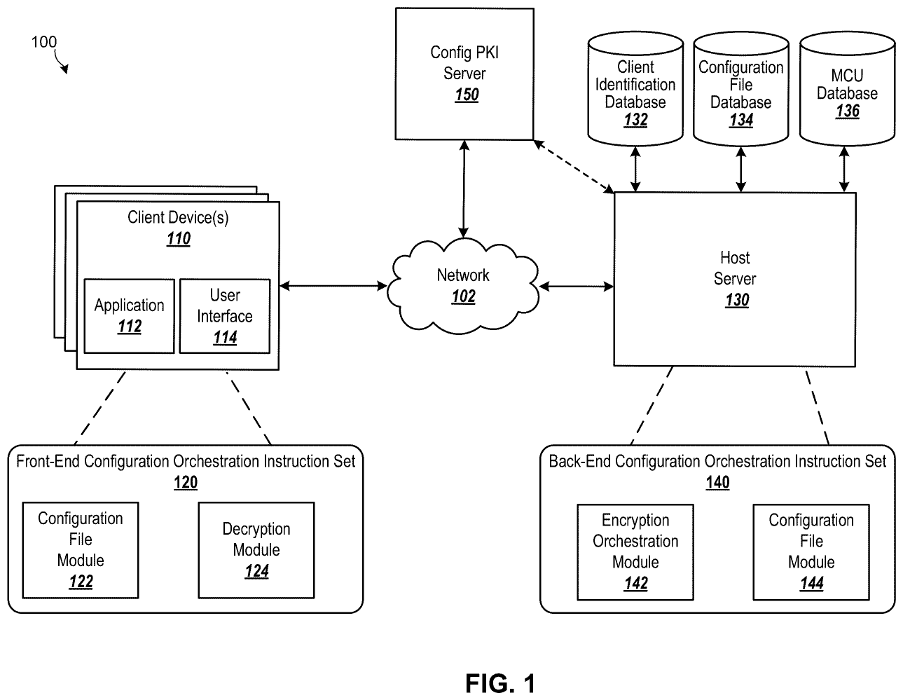

FIG. 1 illustrates an example operating environment 100 for implementing an configuration orchestration of sensitive information process, according to embodiments of the invention. The example environment 100 includes one or more client device(s) 110, a host server 130, and a config PKI server 150 that communicate over a data communication network 102, e.g., a local area network (LAN), a wide area network (WAN), the Internet, a mobile network, or a combination thereof.

A client device 110 can include a desktop, a laptop, a server, or a mobile device, such as a smartphone, tablet computer, wearable device (e.g., smartwatch), in-car computing device, and/or other types of mobile devices. The client device 110 includes applications, such as the application 112, for managing programmable IC orders and an configuration orchestration process to/from the host server 130. The client device 110 can include other applications. Additionally, the client device 110 includes a display that provides a graphical user interface (GUI) 114. Accordingly, if a user of the client device 110 initiates an order via the application 112, corresponding content is generated via the device at user interface 114 and provided at a display of the client device 110 (e.g., a GUI for placing programmable IC orders or managing receiving the configuration files and corresponding decryption keys).

The client device 110 includes a front-end configuration orchestration instruction set 120 that includes a configuration file module 122 and a decryption module 124, according to techniques described herein. In some implementations of the invention, the configuration file module 122 may be utilized by the front-end configuration orchestration instruction set 120 to receive and manage configuration files and the decryption module 124 may be utilized by the front-end configuration orchestration instruction set 120 to receive and manage decryption keys associated with corresponding configuration files. The processes of the configuration file module 122 and the decryption module 124 are further discussed herein.

The host server 130 manages the configuration orchestration for the ordering and providing the programmable ICs as specified by the client device(s) 110, and communication with application 112 from the one or more client devices 110 to receive the orders. In some implementations, the host server identifies a specific client from the client device(s) 110 based on identification information which can be stored in the client identification database 132. The client identification database 132 may also store past order information for previous orders of batches of programmable ICs, and the like.

The host server 130 includes a back-end configuration orchestration instruction set 140 that includes an encryption orchestration module 142 and a configuration file module 144, according to techniques described herein. In some implementations of the invention, the encryption orchestration module 142 may be utilized by the back-end configuration orchestration instruction set 140 to execute the encryption of sensitive information by determining a unique configuration key pair corresponding to a batch of programmable ICs based on the set of configuration elements and manage received from the MCU database 136. For example, upon receiving an order for a given product by a customer for a given customer project, the host server 130 creates in the system a new key pair (e.g., Config_Pr and Config_Pu) bound by an asymmetric cryptography algorithm, such as and not limited to RSA or elliptic curve cryptography (ECC) cryptosystems. In some implementations of the invention, the configuration file module 144 may be utilized by the back-end configuration orchestration instruction set 140 to receive and manage the configuration files from a configuration file database 134. The processes of the encryption orchestration module 142 and a configuration file module 144 are further discussed herein.

The host server 130 may be a front-end server for managing, collecting, processing, and communicating session ID data, user ID information, encrypted configuration files, resource information, etc., from one or more other sources (e.g., a back-end gateway for multiple other servers associated with one or more different entities, such as one or more merchant servers). For example, the host server 130 may be a vendor, such as, inter alia, a chip manufacturer for ordering the programmable ICs as described herein. Alternatively, in some implementations of the invention, the host server 130 may be an intermediary entity for an OEM chip vendor for managing the configuration files and encryption processes described herein. In some implementations of the invention, the configuration file information from the configuration file database 134 and/or the encryption/decryption information (e.g., the unique configuration key pair for the project/customer-specific keys corresponding to the batch of programmable ICs) from the MCU database 136 may also be accessed by the application 112 on the client device 110.

The config PKI server 150 manages the certificates and setting-up a specific PKI, where Config_CA an issuing certificate authority can sign Config public keys and manufacturing each MCU with the Config_CA certificate in a memory protected from overwriting. Using a PKI and a certificate to convey the Config_Pu may allow the MCU to first validate this certificate by using a silicon vendor trust chain (e.g., preprogrammed into the MCU) and prevents anyone from injecting a rogue config. The config PKI server 150 may be a stand-alone server, as illustrated in FIG. 1. Alternatively, in some implementations, the config PKI server 150 may be embedded within the host server 130 or is not connected to the network 102 and in communication only via the host server 130 (e.g., a private PKI configuration setup).

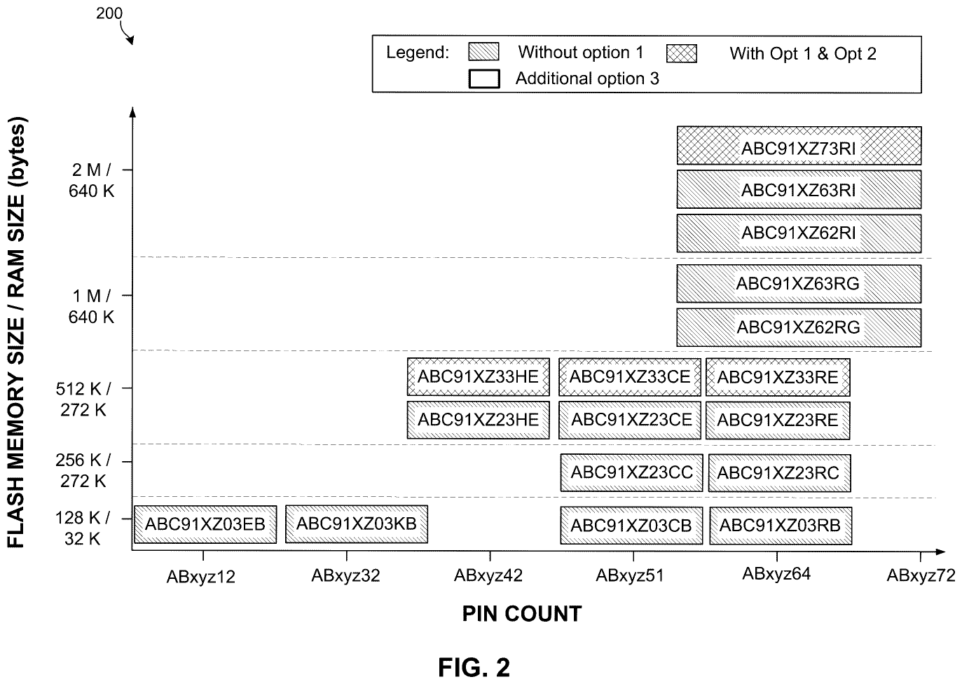

FIG. 2 illustrates an example graph 200 for different product configurations of a manufacturer, according to embodiments of the invention. In particular, the graph 200 provides an example chip family for different product configurations for a silicon chip provider that a client may select. Microcontrollers (MCU), as well as microprocessors (MPU), represent a large global market. With a permanent objective to reduce costs, these two families of products are driving Moore's law and the race to finer lithography and elementary transistor size. But the advantage of smaller dies per silicon wafer is partly offset by the increasing cost of the set of masks used in the many photolithography steps. Furthermore, each MCU is declined into a n×m×p matrix of products which are marketed at different costs for different usage. Behind each MCU, there may be a specific product reference which ties back to a specific silicon die. As a consequence, each MCU family requires an investment in a large number of sets of photolithography masks, and as many wafer and product SKUs down to the sales and distribution chain. All of the above negatively impacts profitability and market prices. FIG. 2 illustrates a portion of an example MCU chip family and the numerous different combinations that a client may order for a batch of programmable integrated circuits (ICs) (e.g., receiving an order at a silicon provider server for a given product by a customer for a given customer project).

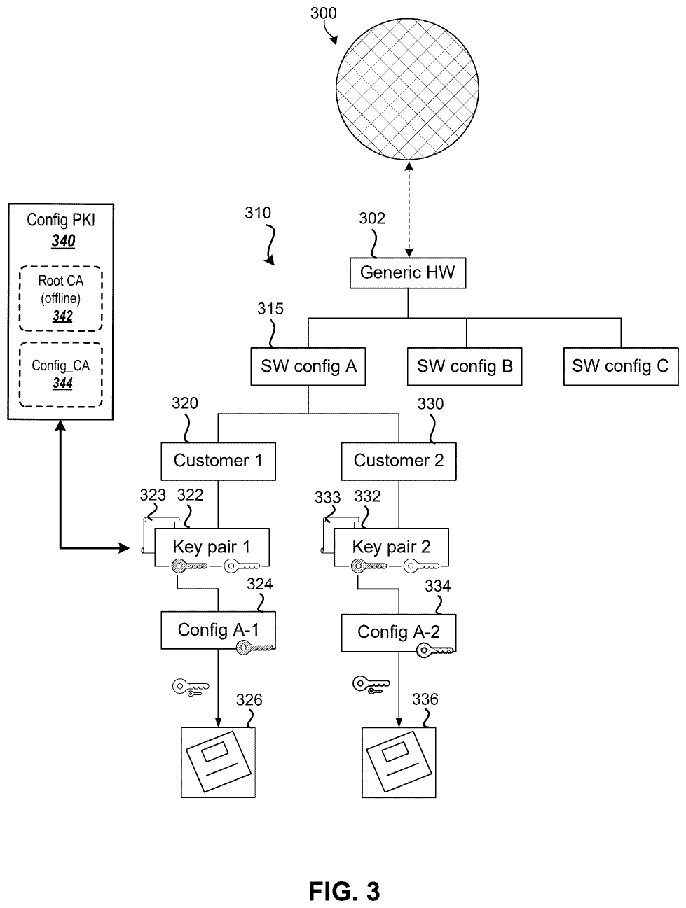

FIG. 3 illustrates an example process of generating a configuration file associated with a selected configuration based on a set of configuration elements, according to embodiments of the invention. In particular, the generic programmable IC silicon wafer 300 may include generic hardware 302 and may be generated by a silicon manufacturer that may include different configurations as selected by a client as illustrated by the configuration tree graph 310. In other words, a client may select a particular configuration of hardware, flash memory size, RAM size, pin count, etc., as illustrated by graph 200 in FIG. 2.

For example, the configuration tree graph 310 of FIG. 3 illustrates generating two different configuration files for two different customers (e.g., customer-1 320 and customer-2 330), based on each selecting the same software configuration (e.g., SW config A 315). However, because each encryption pair is unique to the customer then two different configuration files are generated. For example, customer-1 320, based on its selection of produce features/specifications associated with SW config A 315, a key pair 322 and certificate 323 are generated based on Config A-1 324, and the manufacturer then generates a configuration file 326 based on the SW config A 315, the key pair 322 and certificate 323 and the Config A-1 324. Moreover, customer-2 330, based on its selection of produce features/specifications associated with SW config A 315, a key pair 332 and certificate 333 is generated based on Config A-2 334, and the manufacturer then generates a configuration file 336 based on the SW config A 315, the key pair 332 and certificate2 333 and the Config A-2 334. The configuration certificates 323 and 333 are MCU Pu-encrypted certificates that signed by Config_CA 344 from the Config PKI 340. In some implementations, the Config_CA 344 from the Config PKI 340 is generated based on a Root CA (offline) 342.

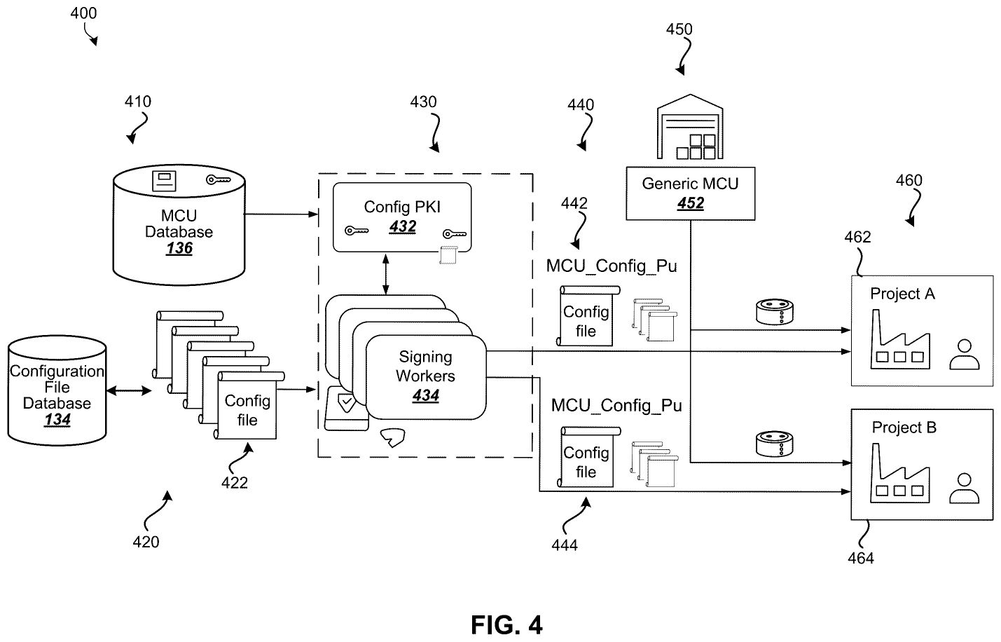

FIG. 4 illustrates an example environment 400 for generating two different chip-level configurations that may be performed by a host server 130 within the operating environment shown in FIG. 1, according to embodiments of the invention. In particular, the example environment 400 provides a back-end of a process at a host server 130 to provide a batch of programmable ICs, with a customized configuration file, and a corresponding batch of decryption certificates to a client device 110 for two different projects (e.g., Project A and Project B). The two different projects may be for two different clients with two different configurations, or two different orders with different configurations from the same client. In other words, a silicon vendor retrieves from a configuration file corresponding to the product requested by a customer and uses a specific configuration to encrypt and sign a configuration file to be used by a generic programmable IC.

The process for generating two different chip-level configurations at example environment 400 includes, after receiving two different configuration orders, at step 410, obtaining a unique public key corresponding to the MCU_Pr from the MCU database 136, and obtaining a configuration file 422 from the configuration file database 134 at step 420. At step 430, the process submits the configuration file 422 to signing and encryption workers 434 interacting with the PKI 432 managing the Config_Pr key and Config_cert certificate. At step 440, the specific updated configuration file 442 and corresponding batch of decryption certificates for project A (the first order) and the configuration file 444 and corresponding batch of decryption certificates for project B (the second order) are generated. At step 450, the process obtains a generic programmable IC (e.g., generic MCU 452) to program based on each updated configuration file (e.g., configuration file 442 for project A, configuration file 444 for project B, etc.). At step 460, the process provides a batch of programmable ICs, with a customized configuration file (e.g., configuration file 442 for project A, configuration file 444 for project B), and a corresponding batch of decryption certificates to a client device 110 for two different projects (e.g., Project A and Project B).

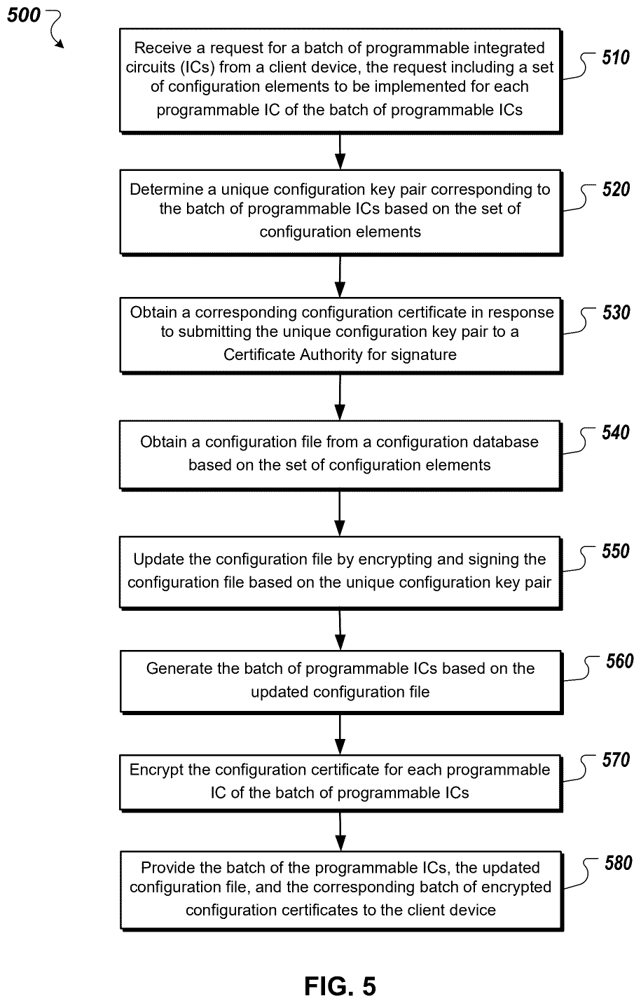

FIG. 5 illustrates a flowchart of an example method 500 for implementing a scalable chip-level personalization process, according to embodiments of the invention. In particular, method 500 mutualizes a common hardware die for a family of products to allow configuration of the hardware on a per customer per project basis with a firmware configuration file with cryptographic properties such that a given configuration for a given customer project and a given batch of microchips cannot be fraudulently reused and applied to another batch of microchips for the same or another project or customer. Operations of the method 500 can be implemented, for example, by a system that includes one or more data processing apparatus, such as one or more client device(s) 110 and/or a host server 130 of FIG. 1. The method 500 can also be implemented by instructions stored on computer storage medium, where execution of the instructions by a system that includes a data processing apparatus cause the data processing apparatus to perform the operations of the method 500.

The system receives a request for a batch of programmable integrated circuits (ICs) from a client device, the request including a set of configuration elements to be implemented for each programmable IC of the batch of programmable ICs (510). For example, an OEM, i.e., a silicon vendor, receives an order for a batch of programmable customized configuration (e.g., receiving an order at a silicon provider server for a given product by a customer for a given customer project).

The system determines a unique configuration key pair corresponding to the batch of programmable ICs based on the set of configuration elements (520). For example, upon receiving an order for a given product by a customer for a given customer project, the silicon vendor creates in the system a new key pair (Config_Pr and Config_Pu) bound by an asymmetric cryptography algorithm, such as and not limited to RSA or elliptic curve cryptography (ECC) cryptosystems. For example, with Config_Pu, the system assembles and submits a CSR (Certificate Signing Request) to the configuration PKI (e.g., config PKI server 150) and retrieves the resulting Config_cert certificate.

The system obtains a corresponding configuration certificate in response to submitting the unique configuration key pair to a Certificate Authority for signature (530). For example, a Certificate Authority (e.g., config PKI server 150), which may be “self-owned” by the host server or may be a standalone PKI Certificate Authority, provides a Config_Pu key into a certificate by a silicon vendor-owned CA. Using a Config_Pu key may prevent a cyber security hack, e.g., should a configuration file leak in clear text, one shouldn't be capable to encrypt it with a rogue private key and forward the corresponding rogue public key to the MCU.

The system obtains a configuration file from a configuration database based on the set of configuration elements (540). For example, as illustrated in FIG. 4, a configuration file 422 from the configuration file database 134 is obtained at step 420.

The system updates the configuration file by encrypting the configuration file based on the unique configuration key pair (550). In some embodiments of the invention, updating the configuration file by encrypting and signing the configuration file based on the unique configuration key pair includes obtaining the configuration file from a configuration database. For example, a silicon vendor retrieves from the configuration database the configuration file corresponding to the product requested by the customer and uses Config_Pr (e.g., Config PKI 432) to encrypt and sign the configuration file (e.g., signing workers information 434).

The system generates the batch of programmable ICs based on the updated configuration file (560). For example, as illustrated in FIG. 4, at step 450 a generic MCU 452 is obtained and personalized with a unique key pair MCU_Pr/MCU_Pu and programmed with the Config_CA certificate.

The system encrypts the configuration certificate (e.g., Config_cert) for each programmable IC of the batch of programmable ICs (570). For example, each generated specific updated configuration file (e.g., configuration file 442 for project A, configuration file 444 for project B, etc.) includes generating a corresponding decryption key associated with the updated configuration file, and thus generating a batch of encrypted configuration certificates corresponding to the batch of ICs to be delivered.

The system provides the batch of the programmable ICs, the updated configuration file, and the corresponding batch of encrypted configuration certificates to the client device (580). For example, as illustrated in FIG. 4, at step 460, the process provides a batch of programmable ICs, with a customized configuration file (e.g., configuration file 442 for project A, configuration file 444 for project B), and a corresponding batch of decryption certificates (Config_cert) to a client device 110 for two different projects (e.g., Project A and Project B).

In some embodiments of the invention, each programmable IC of the batch of the programmable ICs is configured to decrypt the configuration certificate with its unique MCU_Pr key, validate the signature of the certificate using the preprogrammed Config_CA certificate, extract the configuration file public key and validate and decrypt the configuration file. In some embodiments of the invention, decoding of the configuration file by a programmable IC implements a configuration that is based on the set of configuration elements associated with configuration file. For example, at a secure boot, the MCU code may decrypt MCU_Config_cert using the unique MCU_Pr, validate the certificate signature with the Config_CA certificate and compute Config_Pu. The MCU code may then use the Config_Pu to validate the signature and decrypt the configuration file. Moreover, the MCU code may then apply the configuration file and unlock the requested features corresponding to the product ordered.

In some embodiments of the invention, the unique configuration key pair corresponding to the batch of programmable ICs is based on i) a public-key cryptosystem, ii) an elliptic curve cryptography (ECC) cryptosystem (e.g., RSA and ECC asymmetric crypto algorithms), or a combination thereof.

In some embodiments of the invention, the unique configuration key pair corresponding to the batch of programmable ICs is based on i) an advanced encryption standard (AES) algorithm that uses a that uses a 256-bit key (e.g., AES-256 asymmetric crypto algorithms), ii) a keyed-hashing for message authentication algorithm, or a combination thereof. For example, HMAC-SHA256 is an algorithm defined by RFC 2104 (RFC 2104-Keyed-Hashing for Message Authentication). The algorithm may take two byte-strings as input: a key and a message. The output of HMAC-SHA256 is a byte string, called the digest. A Base64 encoding may be performed of this digest to calculate a signature.

In some embodiments of the invention, the unique configuration key pair corresponding to the batch of programmable ICs is based on quantum-resistant algorithms. For example, the RSA or ECC asymmetric algorithms and key material used to sign and encrypt the configuration files may be replaced with quantum-resistant algorithms, such as, inter alia, Crystals-Dilithium and/or Falcon for signing, and Crystals-Kyber for encryption.

In some embodiments of the invention, the unique configuration key pair includes project-specific and client-specific encryption keys associated with a client corresponding to the client device. For example, receiving an order at a silicon provider server for a given product by a customer for a given customer project and generating project/customer-specific keys. Additionally, or alternatively, in some embodiments of the invention, bare public keys are used in the place of x.509 certificates.

In some embodiments of the invention, generating the batch of programmable ICs based on the updated configuration file includes generating a unique serial number for each programmable IC of the batch of programmable ICs. For example, each programmable IC may be identified by a corresponding Serial Number (e.g., stored in the MCU database 136). The silicon vendor (e.g., host server 130) may then retrieve for each programmable IC the corresponding MCU_Pu from the MCU database 136.

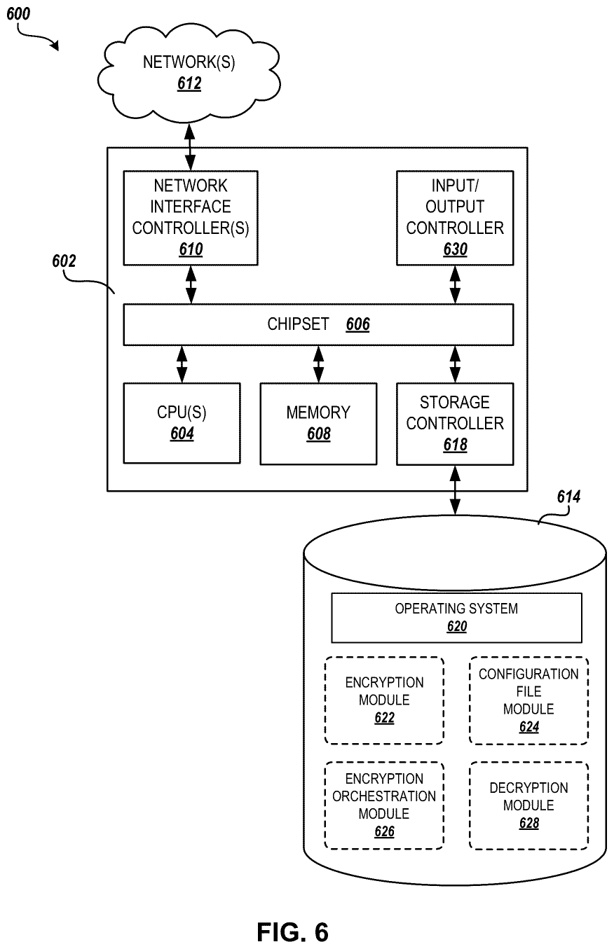

FIG. 6 illustrates an example computer architecture 600 for a computer 602 capable of executing the software components described herein for the sending/receiving and processing of tasks. The computer architecture 600 (also referred to herein as a “server”) shown in FIG. 6 illustrates a server computer, workstation, desktop computer, laptop, a server operating in a cloud environment, or other computing device, and may be utilized to execute any aspects of the software components presented herein described as executing on a host server, or other computing platform. The computer 602 preferably includes a baseboard, or “motherboard,” which is a printed circuit board to which a multitude of components or devices may be connected by way of a system bus or other electrical communication paths. In one illustrative embodiment, one or more central processing units (CPUs) 604 operate in conjunction with a chipset 606. The CPUs 604 can be programmable processors that perform arithmetic and logical operations necessary for the operation of the computer 602.

The CPUs 604 preferably perform operations by transitioning from one discrete, physical state to the next through the manipulation of switching elements that differentiate between and change these states. Switching elements may generally include electronic circuits that maintain one of two binary states, such as flip-flops, and electronic circuits that provide an output state based on the logical combination of the states of one or more other switching elements, such as logic gates. These basic switching elements may be combined to create more complex logic circuits, including registers, adders-subtractors, arithmetic logic units, floating-point units, or the like.

The chipset 606 provides an interface between the CPUs 604 and the remainder of the components and devices on the baseboard. The chipset 606 may provide an interface to a memory 608. The memory 608 may include a random access memory (RAM) used as the main memory in the computer 602. The memory 608 may further include a computer-readable storage medium such as a read-only memory (ROM) or non-volatile RAM (NVRAM) for storing basic routines that that help to startup the computer 602 and to transfer information between the various components and devices. The ROM or NVRAM may also store other software components necessary for the operation of the computer 602 in accordance with the embodiments described herein.

According to various embodiments, the computer 602 may operate in a networked environment using logical connections to remote computing devices through one or more networks 612, a local-area network (LAN), a wide-area network (WAN), the Internet, or any other networking topology known in the art that connects the computer 602 to the devices and other remote computers. The chipset 606 includes functionality for providing network connectivity through one or more network interface controllers (NICs) 610, such as a gigabit Ethernet adapter. For example, the NIC 610 may be capable of connecting the computer 602 to other computer devices in the utility provider's systems. It should be appreciated that any number of NICs 610 may be present in the computer 602, connecting the computer to other types of networks and remote computer systems beyond those described herein.

The computer 602 may be connected to at least one mass storage device 618 that provides non-volatile storage for the computer 602. The mass storage device 618 may store system programs, application programs, other program modules, and data, which are described in greater detail herein. The mass storage device 618 may be connected to the computer 602 through a storage controller 614 connected to the chipset 606. The mass storage device 618 may consist of one or more physical storage units. The storage controller 614 may interface with the physical storage units through a serial attached SCSI (SAS) interface, a serial advanced technology attachment (SATA) interface, a fiber channel (FC) interface, or other standard interface for physically connecting and transferring data between computers and physical storage devices.

The computer 602 may store data on the mass storage device 618 by transforming the physical state of the physical storage units to reflect the information being stored. The specific transformation of physical state may depend on various factors, in different embodiments of the invention of this description. Examples of such factors may include, but are not limited to, the technology used to implement the physical storage units, whether the mass storage device 618 is characterized as primary or secondary storage, or the like. For example, the computer 602 may store information to the mass storage device 618 by issuing instructions through the storage controller 614 to alter the magnetic characteristics of a particular location within a magnetic disk drive unit, the reflective or refractive characteristics of a particular location in an optical storage unit, or the electrical characteristics of a particular capacitor, transistor, or other discrete component in a solid-state storage unit. Other transformations of physical media are possible without departing from the scope and spirit of the present description, with the foregoing examples provided only to facilitate this description. The computer 602 may further read information from the mass storage device 618 by detecting the physical states or characteristics of one or more particular locations within the physical storage units.

The mass storage device 618 may store an operating system 620 utilized to control the operation of the computer 602. According to some embodiments, the operating system includes the LINUX operating system. According to another embodiment, the operating system includes the WINDOWS® SERVER operating system from MICROSOFT Corporation of Redmond, Wash. According to further embodiments, the operating system may include the UNIX or SOLARIS operating systems. It should be appreciated that other operating systems may also be utilized. The mass storage device 618 may store other system or application programs and data utilized by the computer 602, such as encryption module 622 to perform data encryption, a display concealment module 624 for managing concealment an entered password and/or the encrypted password, an configuration orchestration module 626 for managing an encryption/decryption process for a host system, and a decryption module 628 for data decryption, according to embodiments described herein.

In some embodiments, the mass storage device 618 may be encoded with computer-executable instructions that, when loaded into the computer 602, transforms the computer 602 from being a general-purpose computing system into a special-purpose computer capable of implementing the embodiments described herein. These computer-executable instructions transform the computer 602 by specifying how the CPUs 604 transition between states, as described above. According to some embodiments, the mass storage device 618 stores computer-executable instructions that, when executed by the computer 602, perform portions of the method 500, for implementing a scalable chip-level personalization system, as described herein. In further embodiments, the computer 602 may have access to other computer-readable storage medium in addition to or as an alternative to the mass storage device 618.

The computer 602 may also include an input/output controller 630 for receiving and processing input from a number of input devices, such as a keyboard, a mouse, a touchpad, a touch screen, an electronic stylus, or other type of input device. Similarly, the input/output controller 630 may provide output to a display device, such as a computer monitor, a flat-panel display, a digital projector, a printer, a plotter, or other type of output device. It will be appreciated that the computer 602 may not include all of the components shown in FIG. 6, may include other components that are not explicitly shown in FIG. 6, or may utilize an architecture completely different than that shown in FIG. 6.

In general, the routines executed to implement the embodiments of the invention, whether implemented as part of an operating system or a specific application, component, program, object, module or sequence of instructions, or even a subset thereof, may be referred to herein as “computer program code,” or simply “program code.” Program code typically includes computer readable instructions that are resident at various times in various memory and storage devices in a computer and that, when read and executed by one or more processors in a computer, cause that computer to perform the operations necessary to execute operations and/or elements embodying the various aspects of the embodiments of the invention. Computer readable program instructions for carrying out operations of the embodiments of the invention may be, for example, assembly language or either source code or object code written in any combination of one or more programming languages.

The program code embodied in any of the applications/modules described herein is capable of being individually or collectively distributed as a program product in a variety of different forms. In particular, the program code may be distributed using a computer readable storage medium having computer readable program instructions thereon for causing a processor to carry out aspects of the embodiments of the invention.

Computer readable storage media, which is inherently non-transitory, may include volatile and non-volatile, and removable and non-removable tangible media implemented in any method or technology for storage of information, such as computer-readable instructions, data structures, program modules, or other data. Computer readable storage media may further include random access memory (RAM), read-only memory (ROM), erasable programmable read-only memory (EPROM), electrically erasable programmable read-only memory (EEPROM), flash memory or other solid state memory technology, portable compact disc read-only memory (CD-ROM), or other optical storage, magnetic cassettes, magnetic tape, magnetic disk storage or other magnetic storage devices, or any other medium that can be used to store the desired information and which can be read by a computer. A computer readable storage medium should not be construed as transitory signals per se (e.g., radio waves or other propagating electromagnetic waves, electromagnetic waves propagating through a transmission media such as a waveguide, or electrical signals transmitted through a wire). Computer readable program instructions may be downloaded to a computer, another type of programmable data processing apparatus, or another device from a computer readable storage medium or to an external computer or external storage device via a network.

Computer readable program instructions stored in a computer readable medium may be used to direct a computer, other types of programmable data processing apparatus, or other devices to function in a particular manner, such that the instructions stored in the computer readable medium produce an article of manufacture including instructions that implement the functions/acts specified in the flowcharts, sequence diagrams, and/or block diagrams. The computer program instructions may be provided to one or more processors of a general purpose computer, special purpose computer, or other programmable data processing apparatus to produce a machine, such that the instructions, which execute via the one or more processors, cause a series of computations to be performed to implement the functions and/or acts specified in the flowcharts, sequence diagrams, and/or block diagrams.

In certain alternative embodiments, the functions and/or acts specified in the flowcharts, sequence diagrams, and/or block diagrams may be re-ordered, processed serially, and/or processed concurrently without departing from the scope of the embodiments of the invention. Moreover, any of the flowcharts, sequence diagrams, and/or block diagrams may include more or fewer blocks than those illustrated consistent with embodiments of the invention.

The terminology used herein is for the purpose of describing particular embodiments only and is not intended to be limiting of the embodiments of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Furthermore, to the extent that the terms “includes”, “having”, “has”, “with”, “comprised of”, or variants thereof are used in either the detailed description or the claims, such terms are intended to be inclusive in a manner similar to the term “comprising.”

While all of the invention has been illustrated by a description of various embodiments and while these embodiments have been described in considerable detail, it is not the intention of the Applicant to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the spirit or scope of the Applicant's general inventive concept.

What is claimed is:

1. A computer-implemented method comprising:
at an electronic device having a processor:
receiving, at a server, a request for a batch of programmable integrated circuits (ICs) from a client device, wherein the request comprises a set of configuration elements to be implemented for each programmable IC of the batch of programmable ICs;
determining a unique configuration key pair corresponding to the batch of programmable ICs based on the set of configuration elements;
in response to submitting the unique configuration key pair to a Certificate Authority for signature, obtaining a configuration certificate corresponding to the unique configuration key pair;
obtaining a configuration file from a configuration database based on the set of configuration elements;
updating the configuration file by encrypting and signing the configuration file based on the unique configuration key pair;
generating the batch of programmable ICs based on the updated configuration file;
encrypting the configuration certificate for each programmable IC of the batch of programmable ICs; and
providing the batch of programmable ICs, the updated configuration file, and the corresponding batch of encrypted configuration certificates to the client device.

2. The method of claim 1, wherein each programmable IC of the batch of programmable ICs is configured to decrypt and validate the configuration certificate and validate and decode the configuration file.

3. The method of claim 2, wherein decoding of the configuration file by a programmable IC implements a configuration that is based on the set of configuration elements associated with the configuration file.

4. The method of claim 1, wherein the unique configuration key pair and the configuration certificate corresponding to the batch of programmable ICs are based on: i) a public-key infrastructure, ii) an elliptic curve cryptography (ECC) cryptosystem, or a combination thereof.

5. The method of claim 1, wherein the unique configuration key pair and the configuration certificate corresponding to the batch of programmable ICs is based on: i) an Advanced Encryption Standard (AES) algorithm that uses that uses a 256-bit key, ii) a keyed-hashing for message authentication algorithm, or a combination thereof.

6. The method of claim 1, wherein the unique configuration key pair and the configuration certificate corresponding to the batch of programmable ICs are based on a quantum-resistant algorithm.

7. The method of claim 1, wherein the unique configuration key pair and the configuration certificate comprise project-specific and client-specific configuration keys and certificates associated with a client corresponding to the client device.

8. The method of claim 1, wherein updating the configuration file by encrypting and signing the configuration file based on the unique configuration key pair comprises obtaining the configuration file from the configuration database.

9. The method of claim 1, wherein generating the batch of programmable ICs based on the updated configuration file comprises:
generating a unique serial number for each programmable IC of the batch of programmable ICs;
generating and programming one or more unique private and public key pairs each programmable IC of the batch of programmable ICs; and
programming each programmable IC of the batch of programmable ICs with a corresponding certificate.

10. A device comprising:
a non-transitory computer-readable storage medium; and
one or more processors coupled to the non-transitory computer-readable storage medium, wherein the non-transitory computer-readable storage medium comprises program instructions that, when executed by the one or more processors, cause the one or more processors to perform operations comprising:
receiving, at a server, a request for a batch of programmable integrated circuits (ICs) from a client device, wherein the request comprises a set of configuration elements to be implemented for each programmable IC of the batch of programmable ICs;
determining a unique configuration key pair corresponding to the batch of programmable ICs based on the set of configuration elements;
in response to submitting the unique configuration key pair to a Certificate Authority for signature, obtaining a obtaining a configuration certificate corresponding to the unique configuration key pair;
obtaining a configuration file from a configuration database based on the set of configuration elements;
updating the configuration file by encrypting and signing the configuration file based on the unique configuration key pair;
generating the batch of programmable ICs based on the updated configuration file;
encrypting the configuration certificate for each programmable IC of the batch of programmable ICs; and
providing the batch of programmable ICs, the updated configuration file, and the corresponding batch of encrypted configuration certificates to the client device.

11. The device of claim 10, wherein each programmable IC of the batch of programmable ICs is configured to decrypt and validate the configuration certificate and validate and decode the configuration file.

12. The device of claim 11, wherein decoding of the configuration file by a programmable IC implements a configuration that is based on the set of configuration elements associated with the configuration file.

13. The device of claim 10, wherein the unique configuration key pair and the configuration certificate corresponding to the batch of programmable ICs are based on: i) a public-key infrastructure, ii) an elliptic curve cryptography (ECC) cryptosystem, or a combination thereof.

14. The device of claim 10, wherein the unique configuration key pair and the configuration certificate corresponding to the batch of programmable ICs is based on: i) an Advanced Encryption Standard (AES) algorithm that uses that uses a 256-bit key, ii) a keyed-hashing for message authentication algorithm, or a combination thereof.

15. The device of claim 10, wherein the unique configuration key pair and the configuration certificate corresponding to the batch of programmable ICs are based on a quantum-resistant algorithm.

16. The device of claim 10, wherein the unique configuration key pair and the configuration certificate comprise project-specific and client-specific configuration keys and certificates associated with a client corresponding to the client device.

17. The device of claim 10, wherein the operation of updating the configuration file by encrypting and signing the configuration file based on the unique configuration key pair comprises obtaining the configuration file from the configuration database.

18. The device of claim 10, wherein the operation of generating the batch of programmable ICs based on the updated configuration file comprises:
generating a unique serial number for each programmable IC of the batch of programmable ICs;
generating and programming one or more unique private and public key pairs each programmable IC of the batch of programmable ICs; and
programming each programmable IC of the batch of programmable ICs with a corresponding certificate.

19. A non-transitory computer storage medium encoded with a computer program, the computer program comprising a plurality of program instructions that when executed by one or more processors cause the one or more processors to perform operations comprising:
at an electronic device having a processor:
receiving, at a server, a request for a batch of programmable integrated circuits (ICs) from a client device, wherein the request comprises a set of configuration elements to be implemented for each programmable IC of the batch of programmable ICs;
determining a unique configuration key pair corresponding to the batch of programmable ICs based on the set of configuration elements;
in response to submitting the unique configuration key pair to a Certificate Authority for signature, obtaining a obtaining a configuration certificate corresponding to the unique configuration key pair;
obtaining a configuration file from a configuration database based on the set of configuration elements;
updating the configuration file by encrypting and signing the configuration file based on the unique configuration key pair;
generating the batch of programmable ICs based on the updated configuration file;
encrypting the configuration certificate for each programmable IC of the batch of programmable ICs; and
providing the batch of programmable ICs, the updated configuration file, and the corresponding batch of encrypted configuration certificates to the client device.
